(19) United States
(12) Patent Application Publication
(10) Pub. No.: US 2008/0284424 A1
(43) Pub. Date: Nov. 20, 2008

(54) SPIN DETECTION DEVICE AND METHODS FOR USE THEREOF

(75) Inventor: Willem Van Roy, Bierbeek (BE)

Correspondence Address: KNOBBE MARTENS OLSON & BEAR LLP, 2040 MAIN STREET, FOURTEENTH FLOOR, IRVINE, CA, 92614, US

(73) Assignee: Interuniversitair Microelektronica Centrum vzw (IMEC), Leuven (BE)

(21) Appl. No.: 12/180,398

(22) Filed: Jul. 25, 2008

Related U.S. Application Data
(62) Division of application No. 11/282,312, filed on Nov. 18, 2005, now abandoned.
(60) Provisional application No. 60/630,317, filed on Nov. 22, 2004.

(30) Foreign Application Priority Data
Apr. 21, 2005 (EP) EP 5447084.4

(51) Int. Cl. H01L 29/82

(52) U.S. Cl. 324/252; 257/E29.324

(57) ABSTRACT

Embodiments of the invention are related to methods for and devices for performing electrical spin detection. A method for spin detection of charged carriers having a spin and forming a flux in a medium is disclosed, the method comprises measuring a first current on a first contact on the medium that has a first spin selectivity, measuring a second current on a second contact on the medium that has a second spin selectivity, comparing the first measured current and the second measured current, and deriving the average or statistically relevant spin state of the flux of charge carriers. Corresponding devices are disclosed.

### CROSS-REFERENCE TO RELATED APPLICATIONS

This application is a divisional of U.S. patent application Ser. No. 11/282,312, filed Nov. 18, 2005, which claims the benefit under 35 U.S.C. § 119(e) of U.S. Patent Application No. 60/630,317 filed Nov. 22, 2004 for “SPINTRONICS DEVICE AND METHODS FOR USE”, and claims the benefit under 35 U.S.C. § 119(a) of European Patent Application No. EP 5447084.4 filed on Apr. 21, 2005 for “SPINTRONICS DEVICE AND METHODS FOR USE,” which are incorporated by reference.

### BACKGROUND OF THE INVENTION

1. Field of the Invention

The present invention is related to methods and devices for electrical spin detection.

2. Description of the Related Technology

Traditional semiconductor transistors operate through the movement of electrical charge carriers (electrons or holes) in the device. For a long time it has been ignored that these carriers also possess a property called “spin”. Recently a number of spin transistors and other spintronics devices have been proposed [Zutic, Fabian, and Das Sarma, Rev. Modern Physics 76, 323-410 (2004)] that make use of the spin properties or of spin-polarized transport inside the semiconductor.

In general the operation of such a spintronics device may comprise a combination of the following operations:
create or inject spin-polarized carriers in the semiconductor
transport the spin-polarized carriers
manipulate the spin-polarized carriers
store the spin information
retrieve the spin information
detect the polarization of the spin-polarized carriers in the semiconductor, or extract the spin-polarized carriers from the semiconductor.

In order to be able to build circuits consisting of many of these spintronics devices, these operations should be performed in a way that allows large-scale integration. As an example, injection and detection of spin-polarized carriers using an electrical contact leads to much easier integration than optical injection and detection using circularly polarized light. In addition electrical injection and detection are not limited to a subset of semiconductors as is the case for optical injection and detection.

Several of these steps have already been successfully demonstrated, and electrical spin injection is now well established. Electrical spin detection appears to be the reverse operation from injection, and one would have expected that experimental demonstrations would have followed soon after the demonstration of electrical spin injection. However, no large effects have been demonstrated so far: the signals were either unclear, limited to spikes in a very small bias range, or much smaller than expected.

Some methods of spin detection use a single spin-selective contact that allows a current of charge carriers to flow into the contact. Various methods have been used to create a flux of charge carriers with a certain spin-polarization. Some use a beam of circularly polarized light to generate spin-polarized electrons in a GaAs/AlGaAs transport structure, while many proposed spin transistor concepts use an electrical contact to inject spin-polarized carriers into semiconductors such as Si or GaAs.

A common factor between all these experiments is that the amplitude of the current I of charge carriers flowing into the contact is proportional to the number of charge carriers n↑+n↓ (the notations “↑” and “↓” refer to spin-up and spin down states respectively) that are presented to the contact, and with different proportionality factors c↑ and c↓ for both types of spin: I=c↑*n↑+c↓*n↓. The aim of the electrical spin detection contact is then to obtain different currents when the spin-polarization of the incoming flux is changed. One common way of performing the measurement consists of varying the spin-polarization of the incoming flux without changing the total number of carriers, and looking for a change in current into the contact. Another common way is to leave the spin polarization of the incoming flux constant, but to change the proportionality factors of the detector contact. This can e.g. be realized by reversing the magnetization direction of a magnetic contact.

This type of device has shown some spin selectivity, but much less than expected. A problem is that the carriers that are initially rejected by a certain contact will be accepted sometime later, after their spin has been flipped. Let's take an example with a perfectly selective contact that accepts only spin up carriers, i.e. c↓=0. If a spin down electron arrives, it will not be accepted and thus accumulate underneath the contact. After a random time the spin of the carrier will be disturbed, and may flip from spin-down to spin-up. This is a random process where the rate of disturbance is given in terms of a spin-relaxation time.

All the prior art measurements are steady-state measurements, i.e. measurements that are slow compared to the spin-flip time of the carriers in the medium under study. As spin-down carriers keep coming in and are rejected by the contact, more and more of them accumulate underneath the contact. Some of these carriers will see their spin flipped to spin-up, and will be accepted by the contact. At a certain moment (this is after several times the spin-flip time) the number of accumulated spin-down carriers will become so large that the number of carriers that flip from spin-down to spin-up becomes equal to the number of incoming spin-down carriers. When this happens the number of accumulated carriers does not change any longer (this is the so-called steady state condition). The number of carriers that experience a spin-flip event and are accepted by the contact is now equal to the flux of incoming spin-down carriers. In other words, the current into the contact is now identical to the current that would flow if all the incoming carriers had had the right spin to start with.

In other words, in the presence of spin-flip scattering in the medium, a single spin-selective contact loses its spin-selectivity if the time-frame of the experiment is much slower than the characteristic spin-flip time in the medium.

Other methods of spin detection utilize a device with electrical injection and detection contacts that operate under very low bias conditions. When rejected carriers start to accumulate and their density increases, their Fermi-level E_{f} increases. If this increase ΔE_{f} is larger than the applied bias V (|ΔE_{f}|>|qV| where q=1.602×10⁻¹⁹ C is the elementary charge), this will suppress the further injection of “wrong” carriers, and thus lower the current compared to the situation where carriers with the “right” spin are injected. The bias regime where this feed back mechanism functions is called “linear regime”. Under these conditions the device does discriminate between both types of spins. However since this bias range is very small (not substantially larger than 10 mV), these operating conditions are of limited practical use.

Other methods of spin detection use two contacts with a different sensitivity in such a way that they do not accept any current but measure the Fermi-levels of both spin types (or equivalently the Fermi-level of one type of spin together with an average of the two types of spins—the same information can be gained from both configurations). Again this know-how is limited to operating conditions that are of limited practical use, with small signal levels (not substantially larger than 10 mV), and with little drive capability, i.e., where the output can not be used as an input for a second device.

### SUMMARY OF CERTAIN INVENTIVE ASPECTS

Aspects of the present invention concern a method for spin detection of charged carriers having a spin and forming a flux in a transport medium, of the method including:
Providing a flow of charged charge carriers from a starting point at a specific starting time to a first collection contact through the transport medium, wherein the charge carriers travel from the starting point to the first collection contact in a first travel time period,
measuring a first current of charge carriers during a measuring time period in the first collection contact in electrical contact with the transport medium, the first collection contact having a first spin selectivity,
deriving the spin state of the flux of charge carriers during the period, and
removing the charge carriers having a spin state for which the first collection contact is not selective.

In one embodiment, the sum of the measuring time period and the first travel time period is smaller than the average spin flip time and removing the charge carriers includes providing a waiting time in which no flux is present in the transport medium, wherein the waiting time is higher than the average spin flip time. The method can further comprise the step of determining a current integral over time of the current of charge carriers in the first collection contact over the measuring time period.

In another embodiment, removing the charge carriers may include measuring a second current in a second collection contact in electrical contact with the transport medium, the second collection contact having a second spin selectivity different from the first spin selectivity, wherein the charge carriers travel from the starting point to the second collection contact in a second travel time period. The method can further comprise comparing the first current and the second current. The measuring can be started when the spin of the flux of charge carriers is in a steady state. The method according to other aspects of this embodiment may further comprise:
determining a first current integral in time for the first current over a first time period,
determining a second current integral in time for the second current over a second time period,
comparing the first current integral and the second current integral.

The first time period preferably starts after the sum of the starting time and the first travel time and the second time period preferably starts after the sum of starting time and second travel time. The duration of the first time period and second time period are preferably smaller than the average spin flip time minus the first travel time and smaller than the average spin flip time minus the second travel time, respectively.

Another embodiment provides for a device for performing spin detection, that includes:
a transport medium, allowing for transport of charge carriers having a spin;
a charge carrier source for providing a flux of charge carriers into the transport medium
means for statistically controlling the spin of the charge carriers at a predetermined moment in time;
a first collection contact in electrical contact with the transport medium, the first collection contact having a first spin-selectivity;
a first current measuring device arranged to measure the current in the first collection contact;
a second collection contact in electrical contact with the transport medium, the second collection contact having a second spin-selectivity;
a second current measuring device arranged to measure the current in the second collection contact;

wherein the first selectivity is different from the second selectivity and whereby the flux of charge carriers is guided towards the first and the second collection contacts from the predetermined moment in time. The first collection contact or second collection contact is preferably one of a magnetic metal; a ferromagnetic metal; a ferrimagnetic metal; a tunnel injector selected from the group consisting of a magnetic metal with a tunnel barrier, a non-magnetic metal with a magnetic tunnel barrier, a magnetic metal with a magnetic tunnel barrier, a ferromagnetic metal with a tunnel barrier, a non-ferromagnetic metal with a magnetic tunnel barrier, a ferromagnetic metal with a magnetic tunnel barrier, a ferrimagnetic metal with a tunnel barrier, a non-ferrimagnetic metal with a magnetic tunnel barrier, a ferrimagnetic metal with a magnetic tunnel barrier; a half-metallic ferromagnet, a half-metallic ferrimagnet, a half-metallic antiferromagnet, a magnetic semiconductor, and a ferromagnetic semiconductor. In one aspect of this embodiment, the charge carrier source comprises an electrical injection contact. Advantageously, the injection contact has a predetermined magnetic polarization and the injection contact functions as the means for statistically controlling the spin of the charge carriers. The means for statistically controlling the spin of the charge carriers is may be one of a electromagnetic field localized at a specific position along the path of the charge carriers in the transport medium, an optical injection means, the result of a spintronic action, manipulation, operation, filter or calculation, or the result of a quantum computing or quantum cryptography operation.

In one aspect of this embodiment, the charge carrier source is preferably arranged to provide a potential difference between the injection contact and the first and the second collection contacts. In certain embodiments, the first collection contact and the second collection contact have a different spin polarization. The first collection contact and the second collection contact preferably have different magnetization directions, forming an angle different from zero or having a different amplitude or magnitude.

The injection contact and the first and the second collection contact may be positioned on the same side or on different sides of the transport medium.

In another embodiment the transport medium comprises a semiconductor material or a metal.

Another embodiment provides for a device for performing spin detection, including:
a transport medium, allowing for transport of charge carriers having a spin;
means for providing a flux of charge carriers into the transport medium;
means for statistically controlling the spin of the charge carriers at a predetermined moment in time;
a first collection contact; and
a means for measuring the current in the first collection contact.

The device may be characterized in that all elements or components present in the detector or detector chain are ultrafast elements.

Another embodiment provides for a method for information transfer, including:
Providing information to transfer,
encoding the information into a bit stream with an encoder,
mapping the bit stream onto a block signal having a constant block frequency, the block signal being a periodical flux of charged carriers having a spin, wherein the average spin state of the active period is correlated with the bit content,
Providing a transport means for the block signal.
Applying any of the methods according to the present invention for measuring the spin for each of the active periods of the block signal, and
Decoding the spin information into a bitstream.

Embodiments of the present invention provide for methods and devices for electrical spin detection, which alleviates or avoids the problems of the prior art.

Various embodiments provide for methods and devices that lead to an improved electrical spin detection. Embodiments of the invention may be used in any device that combines electrical spin detection with other operations such as those listed below or others:
create or inject spin-polarized carriers in the semiconductor
transport the spin-polarized carriers
manipulate the spin-polarized carriers
store the spin information
retrieve the spin information
detect the polarization of the spin-polarized carriers in the semiconductor, or extract the spin-polarized carriers from the semiconductor

The time after which the spin of an individual particle is disturbed varies stochastically. When considering an ensemble of particles the average rate at which spins are disturbed is characterized by the spin relaxation time. More exactly, the spin relaxation time is the time after which the spin of about 63.21% of the particles has been disturbed (where 63.21%=(1−1/e) with e the base of the natural logarithm). This spin relaxation time is also the parameter which characterizes the speed with which a non-equilibrium ensemble of particles evolves towards the equilibrium state.

In the description the following terms are used and are known to those of skill in the art, but an additional definition is given below:
the magnetization M (of for instance a collection contact):

$$M ∝ \frac{n ↑ + n ↓}{volume}$$

the polarization P (of for instance a collection contact)

$$P = \frac{n ( {E}_{f} ) ↑ - n ( {E}_{f} ) ↓}{n ( {E}_{f} ) ↑ + n ( {E}_{f} ) ↓}$$

It may be noted that M/P=constant. “Volume” is the physical volume of the element (for instance a collection contact). E_{f} is the Fermi Energy.

The current polarization is similarly P_{I}=(I↑−I↓)/(I↑+I↓) where I↑ and I↓ are the currents carried by carriers with spin up and spin down, respectively. Depending on how the transport mechanism exactly works, the currents I↑ and I↓ can be proportional with n↑ and n↓ or with the densities weighed with the Fermi velocity VF to a certain power i: n↑ v_{F}̂i and n↓ v_{F}̂i, where the exponent i can be 1 or 2 or other values.

Another embodiment provides for a device for performing spin detection, the device including:
a transport medium, allowing for transport of charge carriers having a spin;
means for providing a flux of charge carriers into the transport medium
means for statistically controlling the spin of the charge carriers at a predetermined moment in time; (with “statistically controlling” is meant that the distribution of states of the charge carriers is known with a reasonable degree of certainty (for instance more than about 10%, 20%, 30%, 40%, 50%, 60%, 70%, 80%, 90%, 95%, 99%). As a limiting case, the states of the charge carriers may be known with 100% certainty.)
a first collection contact; —this may be, for example, a magnetic metal, a ferromagnetic metal, a ferrimagnetic metal, a tunnel injector [(i) a magnetic metal with a tunnel barrier (ii) a non-magnetic metal with a magnetic tunnel barrier (iii) a magnetic metal with a magnetic tunnel barrier, (ib) a ferromagnetic metal with a tunnel barrier (iib) a non-ferromagnetic metal with a magnetic tunnel barrier (iiib) a ferromagnetic metal with a magnetic tunnel barrier, (ic) a ferrimagnetic metal with a tunnel barrier (iic) a non-ferrimagnetic metal with a magnetic tunnel barrier (iiic) a ferrimagnetic metal with a magnetic tunnel barrier], a half-metallic ferromagnet, a half-metallic ferrimagnet, a half-metallic antiferromagnet, a magnetic semiconductor, a ferromagnetic semiconductor, —any of the above tunnel injectors with a magnetic or ferromagnetic semiconductor instead of the magnetic or ferromagnetic metal—having a first spin-selectivity onto the transport medium; (the spin-selectivity can be defined as S=(I↑−I↓)/(I↑+I↓) where I↑ and (I↓) are the currents of charge carriers flowing from the semiconductor into the contact under given bias conditions and a given number of charge carriers that all have their spin up (down). S can thus depend on, for example, bias-conditions.
a first means for measuring the current in the first collection contact. Such a current measuring means can be an amperemeter, a transistor, a chip, a multimeter, or any other means which can measure current.
a second collection contact having a second spin-selectivity onto the transport medium; the same possibilities as the first collection contact can be used.
a second means for measuring the current in the second collection contact.
wherein the first selectivity is different from the second selectivity and whereby the flux of the charge carriers is guided towards the first and the second collection contacts from the predetermined moment in time.

Materials used may include:
Ferromagnetic metals: Iron, Cobalt, Nickel and their alloys and compounds, transition metals and their alloys and compounds, rare earth metals and their alloys and compounds, magnetic oxides, magnetic semiconductors
HMF (half-metallic ferromagnets): Heusler alloys (NiMnSb, PtMnSb, Co2MnSi, CoMnGe, . . . ), Fe3O4 (magnetite), Cr2O3, La1/3 Sr2/3 MnO3
Ferromagnetic semiconductors: (Ga,Mn)As, (In,Mn)As, (Ga,Mn)N, SiMn, GeMn and the equivalent combinations with Cr, Ni, Fe, Co instead of Mn,
II-VI Magnetic semiconductors,
Chalcopyrites,
Magnetic oxide semiconductors (e.g. ZnO:Co, TiO2:Co, HFO2)

In certain embodiments, the means for providing the flux of the charge carriers can be an electrical injection contact.

In preferred embodiments, the injection contact has a predetermined magnetic polarization and the injection contact consequently functions as the means for statistically controlling the spin of the charge carriers.

The means for statistically controlling the spin of the charge carriers may be a electromagnetic field, localized at a certain position along the path of the charge carriers in the transport medium. In certain embodiments, the statistically controlling means may be one of an optical injection means, a result of a spintronic action/manipulation/operation/calculation, and a result of a quantum computing or quantum cryptography operation.

In certain embodiments, the means for providing a flux of charge carriers further comprises a potential difference between the injection contact and the first and the second collection contacts.

In certain embodiments, the first collection contact and the second collection contact can have a different spin polarisation.

The first collection contact and the second collection contact have different magnetization directions, forming an angle different from zero, for example, but not only 180 or 90 degrees.

The injection contact and the first and the second collection contact can be positioned on the same side or on different sides such as, for example, on opposite sides of the transport medium.

The transport medium may comprise a semiconductor material or a metal such as, for example; an illustrative but not extensive list is given below.

Metals may be one of Lithium, Beryllium, Sodium, Magnesium, Aluminium, Potassium, Calcium, Titanium, Vanadium, Chromium, Manganese, Iron, Cobalt, Nickel, Copper, Zinc, Arsenic, Zirconium, Molybdenum, Silver, Gold, Cadmium, Antimony, Barium, Osmium, Platinum, Palladium, Mercury, Thallium, Lead, Uranium, and their alloys and compounds

Semiconductor materials may be one of Group IV elemental semiconductors: Boron (B), Diamond (C),Silicon (Si),Germanium (Ge),Gray Tin (Sn), Phosphorus (P), Selenium (Se), Tellurium (Te); Group IV compound semiconductors: Silicon carbide (SiC), Silicon germanide (SiGe), Boron-Carbon (BC), Boron-Silicon (BSi), Boron-Phosphorus (BP),Silicon-Tin (SiSn), Germanium-Tin (GeSn); Group III-V semiconductors: Boron nitride (BN),Boron Phosphide (BP), Boron Arsenide (BAs), Aluminum antimonide (AlSb),Aluminum arsenide (AlAs), Aluminum nitride (AlN), Aluminum phosphide (AlP), Gallium antimonide (GaSb), Gallium arsenide (GaAs), Gallium nitride (GaN), Gallium phosphide (GaP), Indium antimonide (InSb), Indium arsenide (InAs), Indium nitride (InN), Indium phosphide (InP); Group III-V ternary, quaternary, . . . semiconductor alloys: Aluminum gallium arsenide (AlxGa1−xAs), and other combinations of the above III-V semiconductors; Group II-VI semiconductors: Cadmium selenide (CdSe), Cadmium sulfide (CdS), Cadmium telluride (CdTe), Zinc oxide (ZnO), Zinc selenide (ZnSe), Zinc sulfide (ZnS), Zinc telluride (ZnTe), Mercury selenide (HgSe), Mercury sulfide (HgS), Mercury telluride (HgTe); Group II-VI ternary, quaternary, . . . semiconductor alloys: Cadmium mercury telluride ((Cd,Hg)Te), and other combinations of the above II-VI semiconductors; Group I-VII semiconductors: Cuprous chloride (CuCl); Group IV-VI semiconductors: Lead sulfide (PbS), Lead telluride (PbTe), Tin sulfide (SnS), Layered semiconductors, Lead iodide (PbI2), Molybdenum disulfide (MoS2), Gallium Selenide (GaSe), Miscellaneous oxides, Copper oxide (CuO), Cuprous oxide (Cu2O), Organic semiconductors, Magnetic semiconductors; Ternary Adamantine Semiconductors; Ternary Analogs of the III-V Adamantine Semiconductors; the II-IV-V2 Compounds (Ternary Pnictides); the I-IV2-V3 Compounds; Ternary Analogs of II-VI Adamantine Semiconductors; I-III-VI2 Compounds; I2-IV-VI3 Compounds; I3-V-VI4 Compounds; Defect Adamantine Semiconductors; IV3-V4 Compounds; III2-VI3 Compounds; Defect Ternary Compounds, III2-IV-VI Compounds; Non-Adamantine Semiconductors and Variable-Composition Semiconductor Phases, IA-IB Semiconductors, Semiconductors in the I-V Binary Systems, IA-VB Compounds, (IA)3-VB Compounds, I-VI Compounds, Copper and Silver Oxides, Copper and Silver Chalcogenides, II2-IV Compounds with Antifluoride Structure, IV-VI Galenite Type Compounds, V2-VI3 Compounds, Binary Compounds of the Group VIIIA Elements, Semiconductor Solid Solutions, Alloys of Elemental Semiconductors, III-V/III-V Semiconductor Alloys, II-VI/II-VI Solid Solutions, Solid Solutions of II-VI and III-V Compounds, and Organic Semiconductors.

A corresponding method for spin detection of charged carriers having a spin and forming a flux in a medium, comprising the steps of:
measuring a first current on a first contact on the medium that has a first spin selectivity;
measuring a second current on a second contact on the medium that has a second spin selectivity;
comparing the first current and the second current;
derive the average or statistically relevant spin state of the flux of charge carriers.

In certain embodiment the measurements can start when the spin of the flux of charge carriers is saturated.

In a certain further embodiment the method further comprises the steps of:
determining a starting time and place, determined as the last moment in time at which the spin of the charge carriers is statistically controlled.
determining a first current integral in time for a certain duration in time.
determining a second current integral in time for the certain duration in time.
comparing the first current integral and the second current integral.

In certain embodiments, the first current integral and the second current integral are determined over a collection contact dependent period, respectively, starting at starting time+delay time 1 and starting time+delay time 2.

Advantageously, delay time 1 and delay time 2 may be the times necessary for the charge carrier flux to bridge the distance between the starting place and the first and the second collection contact respectively added to the time necessary for a charge carrier to diffuse between the first contact and the second contact.

In certain embodiments this duration in time is smaller than the average spin flip time−delay 1 and smaller than the average spin flip time−delay 2.

In another aspect of the present invention a device for performing spin detection is disclosed, comprising:
a. a transport medium, allowing for transport of charge carriers having a spin; [see device embodiments above]
b. means for providing a flux of charge carriers into the medium [see device embodiments above];
c. means for statistically [see device embodiments above] controlling the spin of the charge carriers at a predetermined moment in time;
d. a collection contact; and
e. a means for measuring the current in the first collection contact.

In certain embodiments, all elements or components present in the detector or detector chain are ultrafast elements.

A corresponding method for spin detection of charged carriers having a spin and forming a flux in a medium, the flux having active and inactive periods [the inactive periods should last longer than N*spin relaxation time, N, e.g. =about 1, 2, 3, 4, 5, 6, 7, 8, 9, 10, 20, 50, 100] comprising:
determining a starting time and place, determined as the last moment in time at which the spin of the charge carriers is statistically controlled for an active period.
measuring a current in a first contact on the medium that has a certain spin selectivity over a certain period in time.
deriving the average or statistically relevant spin state of the period of flux of charge carriers.

This method may further comprise determining a current integral over time of the current over a certain range in time.

Advantageously the range can defined by [starting time+delay time, starting time+delay time+duration], whereby delay time+duration<average spin flip time.

Here the delay time is preferably the time necessary for the charge carrier flux to bridge the distance between the starting place and the collection contact.

In another aspect of the present invention, a method for information transfer is disclosed based on the methods and devices disclosed above comprising:
getting information
encoding information into a bit stream by means of an encoder
mapping the bit stream onto a block signal having a constant block frequency, the block signal being a periodical flux of charged carriers having a spin, wherein the average spin state of the active period is correlated with the bit content.
Providing a transport means for the block signal.
Applying any of the methods according to the present invention already described before for measuring the spin for each of the active periods of the block signal.
Decoding the spin information into a bitstream

### BRIEF DESCRIPTION OF THE DRAWINGS

FIG. 1 is an illustration of a device according to an embodiment of the present invention, also related to a time resolved measurement method.

FIG. 2 is a more specific variation of the device depicted in FIG. 1, wherein the means for providing a flux of charge carriers in the medium is an injection contact.

FIG. 3 is an illustration of a device according to an embodiment of the present invention, utilizing a differential measurement method, wherein 2 collection electrodes are present.

FIG. 4 shows the device of FIG. 3 with electrodes on different sides of the transport medium. The interdistance (or times necessary to bridge those distances) between an injection electrode (or a last position of statistical control of the states of the charged carriers in the flux) and the collection electrode or electrodes is of importance as described in the text.

FIG. 5 shows the device of FIG. 3 wherein means for providing a flux of charge carriers in the medium is an injection contact.

FIG. 6 shows the embodiment of FIG. 5, wherein the collection contact electrodes are situated on different surfaces or sides of the transport medium.

FIG. 7 shows some typical signals which can be used for the method and devices relating to the time resolved measurements. The active and inactive periods may have different lengths. One may be longer or shorter than the other.

FIG. 8 shows how a signal such as shown in FIG. 7 can be applied to a device according to an embodiment of the present invention.

FIG. 9 illustrates a circuitry configuration which can be used for the differential measurement method and corresponding devices.

### DETAILED DESCRIPTION OF CERTAIN INVENTIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

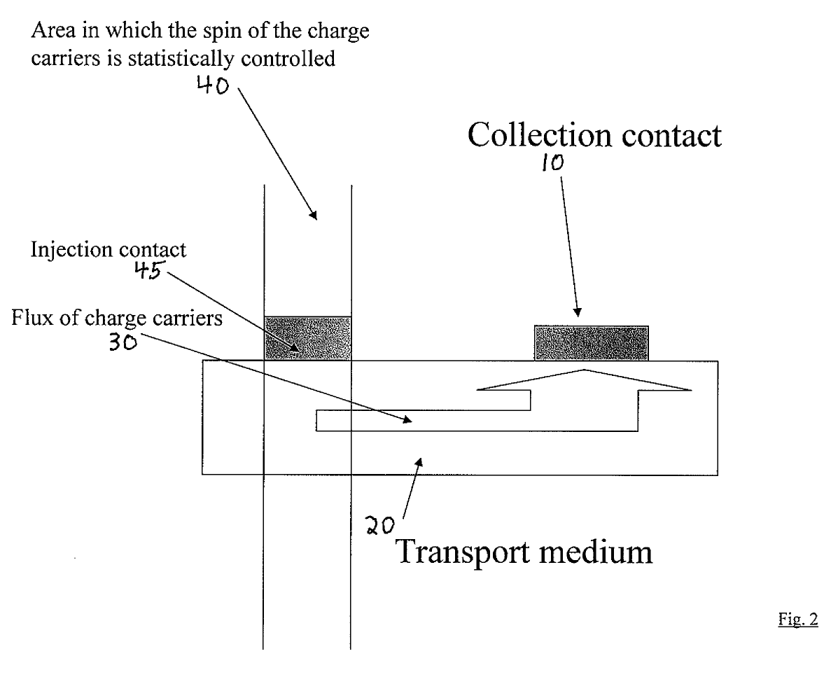

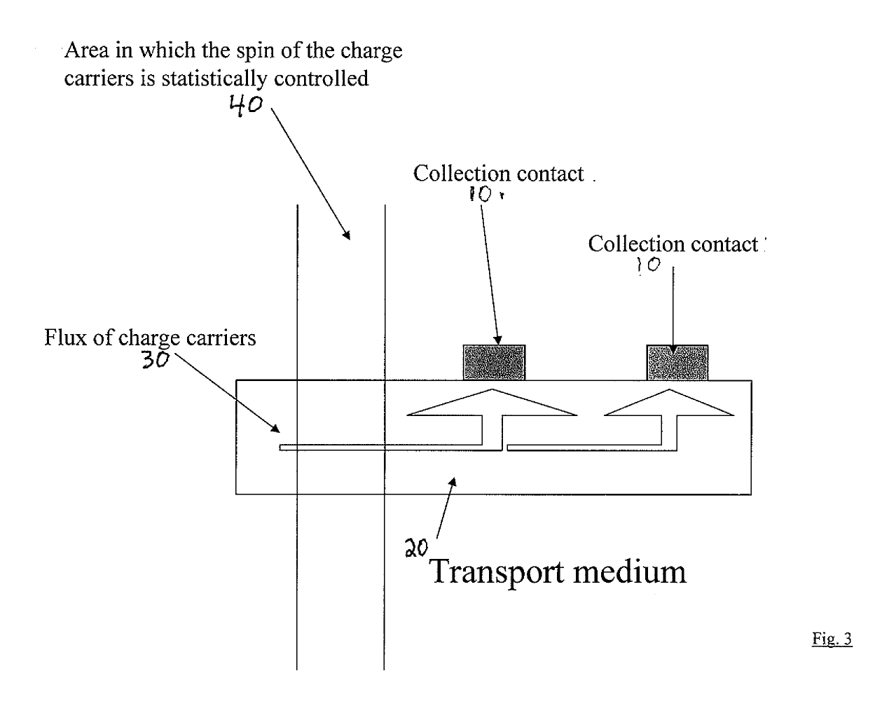

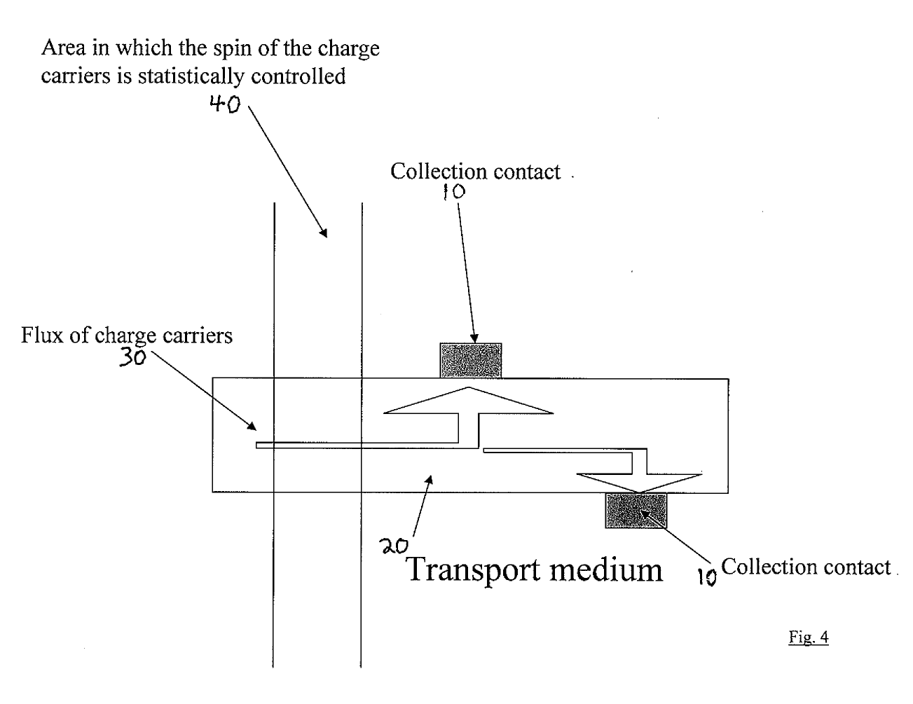

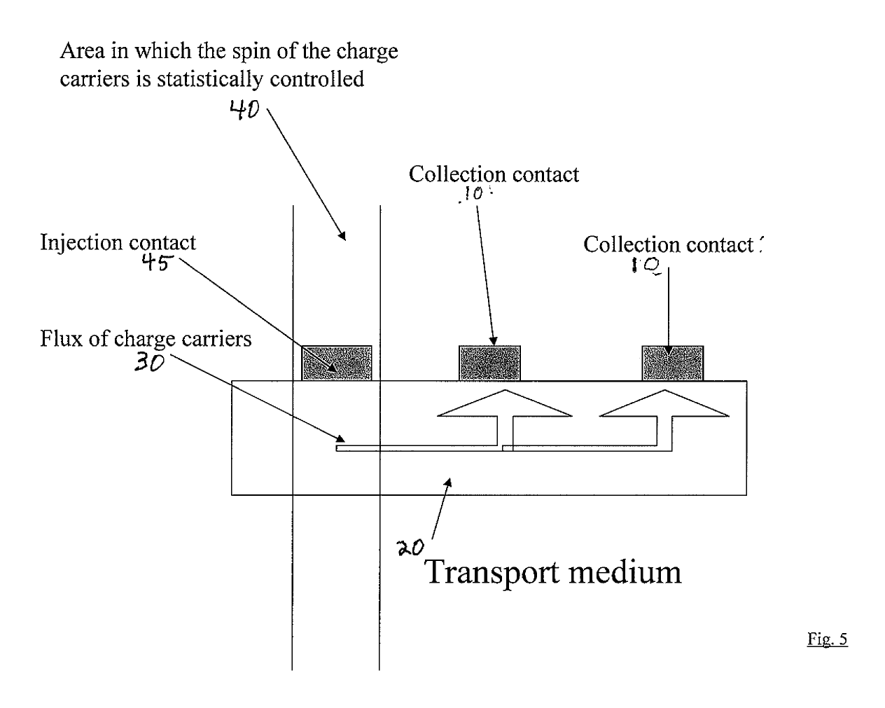

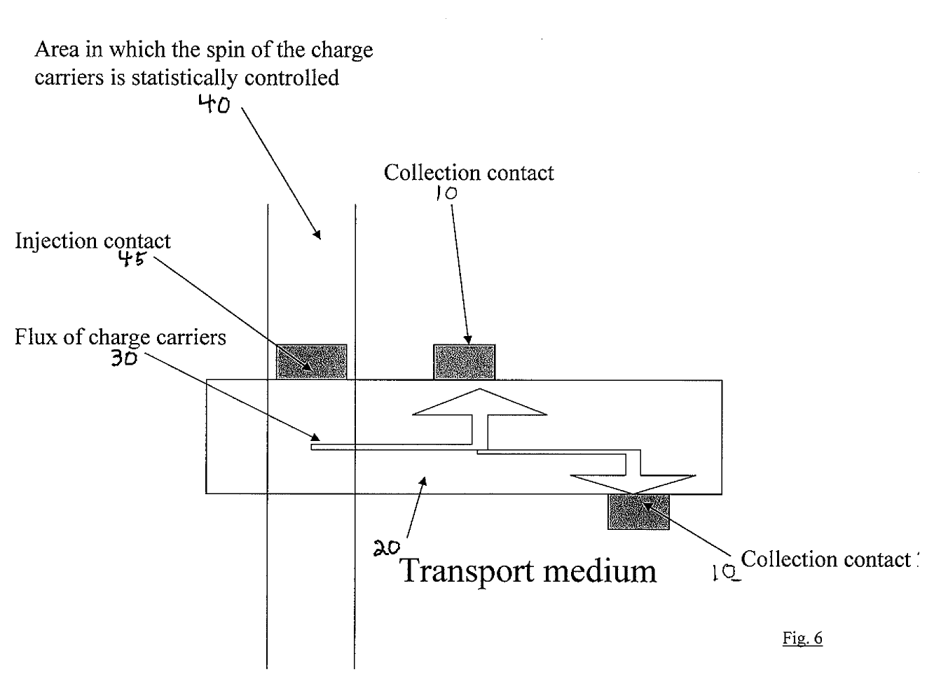

An object of certain embodiments of the present invention is a device that comprise two electrical current contacts 10 (used as spin detectors) that have a different spin sensitivity. FIGS. 3 through 6 illustrated certain aspects of these embodiments containing wherein two collection electrodes are present. These contacts are placed on a transport medium 20 (e.g. a semiconductor or a metal), in which a spin-polarized charge carrier density can be created. Some examples of statistical controller means for creating a spin polarized carrier (See FIGS. 2, 5 and 6 for injection contacts 45) include but are not limited to: an electrical contact that can inject spin-polarized carriers in the transport medium 20; a beam of circularly polarized light that can inject spin-polarized carriers in the transport medium 20; a magnetic field that polarizes the charge carriers; a spin filter that polarizes the charge carriers; a spintronics device or circuit that transports, manipulates, filters, or performs logic operations on spin polarized carriers that have been injected at one or more other places.

The different spin sensitivity of the two detector contacts 10 may be the result of using two materials with different magnetic properties (e.g. two different magnetic materials, or a magnetic and a non-magnetic material), or using two spin-polarized contacts comprising magnetic materials with magnetizations pointing in different directions (the angle between the two magnetizations can e.g. be 180°, or 90°, or any other angle different from 0°; the two magnetic materials can be but need not be identical). The best discrimination will be obtained when the contacts are fully spin-polarized (+100% or −100% polarized, i.e., the current in them is carried by carriers with one type of spin only), and when their polarizations are opposite (i.e., 180° apart). For brevity the following paragraph(s) will be written under this assumption, with the understanding that devices with other configurations will operate with an accordingly reduced discrimination between both spins, but still with the same relative improvement over existing devices with only one detection contact.

The two spin-detector contacts 10 are placed within a small distance from each other, where small is in comparison with the spin diffusion length for the relevant carriers (electrons or holes) inside the transport medium 20, such that spins that are rejected by a certain contact have a large chance to be absorbed/extracted/removed by the other contact with the opposite spin-sensitivity, compared to the chance that their spin will be flipped and that the charge is extracted by the contact that originally rejected it.

Another object of certain embodiments of the present invention is a method to detect the spin of charge carriers in a medium 20, using electrical contacts 10. The method consists of having a medium in which charge carriers are present that can have a spin polarization, and of which one wants to determine this spin polarization.

On the medium 20, two detector contacts 10 are present that have a different spin sensitivity. The distance between these contacts is preferably smaller than N times the spin diffusion length [e.g., N=10, 5, 4, 3, 2, 1, 0.9 to 0.1, 0.01, 0.001], such that there is a significant (theoretically non-zero) probability that a carrier that is rejected by one of the contacts, because it has the wrong spin, will reach the second contact and attempt to enter there before its spin is flipped, thus before it becomes possible for this carrier to enter the contact that originally rejected it.

In a preferred embodiment, the distance is smaller than the spin diffusion length.

In certain embodiments the distance between the (optional) injection contact 45 or the latest place for which statistical control of the particle states in the flux 30 of particles is present (area 40 in Figures), and one or both of the collection contacts 10, is smaller than N′ times the spin diffusion length [e.g., N′=10, 5, 4, 3, 2, 1, 0.9, 0.8, 0.7, 0.6, 0.5, 0.4, 0.3, 0.2, 0.1, 0.01, 0.001]. N′ for one of the collection contacts 10 may be different from N for the other collection contact 10.

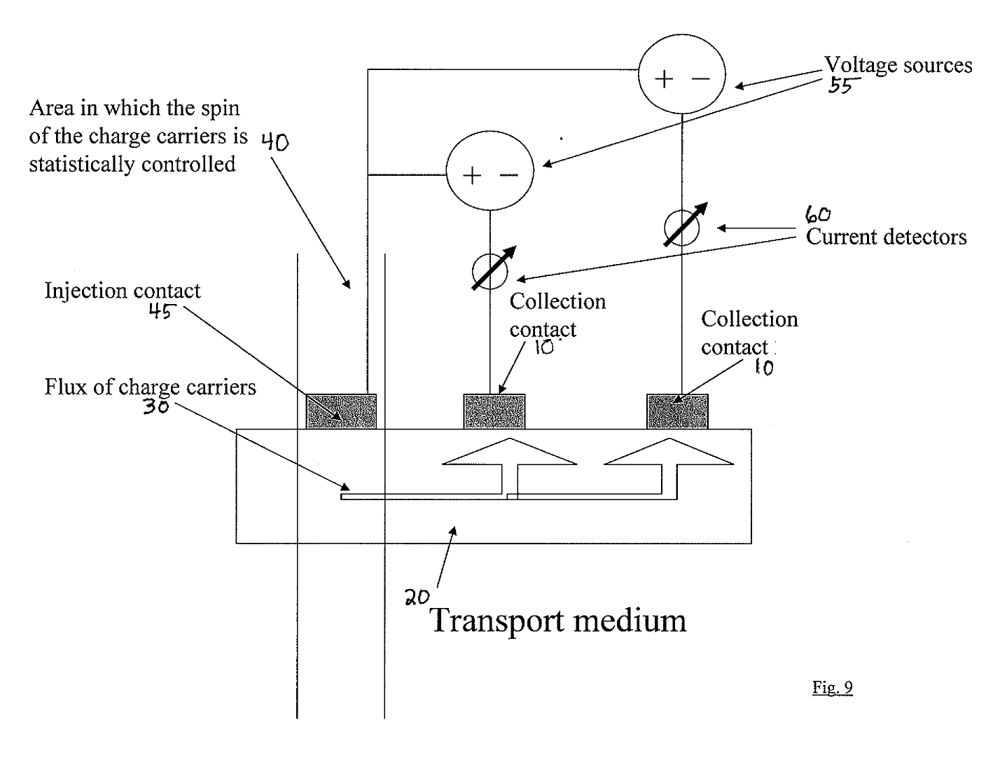

In one embodiment, the method comprises measuring a first current on the first contact with a first spin selectivity on the medium 20, measuring a second current on the second contact with a second spin selectivity on the medium 20, comparing the first current and the second current, and deriving the average or statistically relevant spin state of the charge carriers present in the medium 20. FIG. 9 illustrates a circuitry configuration, including two voltage sources 55 and two current detectors 60, which may be used for the differential measurement method and corresponding devices of this embodiment.

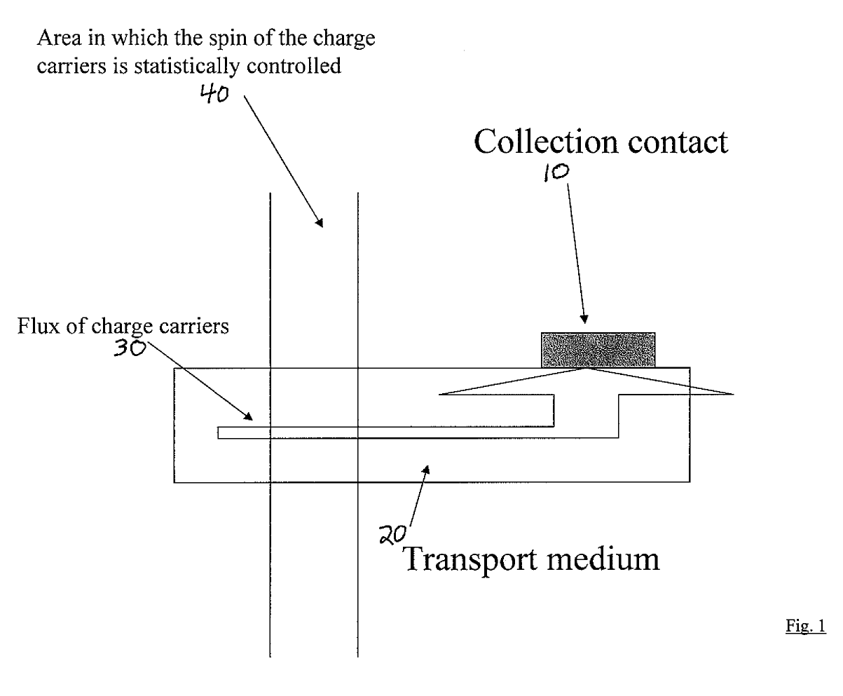

Another object of certain embodiments of the present invention is a device for time-resolved measurements of the spin polarization. FIG. 1 is an illustration of a device related to the time resolved measurement method. FIG. 2 is a more specific variation of the device depicted in FIG. 1, wherein a flux provider means for providing a flux of charge carriers in the medium 20 is an injection contact 45. Devices according to these certain embodiments may be similar to the prior art devices that have a single spin detector, but they have improvements that the necessary contacts and the measurement circuits allow for fast measurements compared to the spin relaxation time of the charge carriers. This time depends on the type of carrier and the properties of the transport medium 20. [Zutic, Fabian, and Das Sarma, Rev. Modern Physics 76, 323-410 (2004)—referred to herein as the ZFD paper] give a recent review of the known spin relaxation times (sometimes also called spin flip time and denoted T_{sf}) in many semiconductors. Some values are reproduced below. From herein, references to the ZFD paper will appear as ZFD p. xyz, where xyz gives the actual page number within the ZFD paper.
electrons in Si, at 4.2 K: T_{sf} of about 30 ms in very clean Si/SiGe two-dimensional electron gases, T_{sf} is shorter in samples with higher doping levels or higher levels of impurities, or with structural defects. We note that in bulk n-Si the carriers freeze out at this temperature for doping concentrations below about 1*10¹⁸ cm⁻³. The high doping levels required to prevent freeze-out will result in spin relaxation times shorter than the value cited above.
electrons in Si at higher temperatures such as room temperature: T_{sf} is shorter than at 4.2 K.
holes in Si: no actual data have been reported, however it is known that T_{sf} is smaller than the spin relaxation time for electrons in Si at the same temperature.
electrons in bulk GaAs [see ZFD p. 363]: largest reported values are 130-180 ns at 4.2 K for n-type doping concentrations of 3*10¹⁵ to 2*10¹⁶ cm⁻³. The spin relaxation time drops quickly with increasing doping concentration to 0.2 ns=200 ps at 1*10¹⁸ cm⁻³.
electrons in GaAs at higher temperatures [see ZFD p. 364]: for an n-type doping concentration of 1*10¹⁶ cm⁻³: T_{sf}=130 ns at 4.2 K, 10 ns at 50 K, 1.2 ns at 100 K, 600 ps at 150 K.

All other examples of this paper can be used to illustrate the functioning of the methods and devices according to embodiments of the present invention.

These so called spin flip or spin relaxation times set the lower limit on the speed that separates “fast” from “slow” spin detectors. A spin detector consists of different elements or component, each with its own characteristics. To build a “fast” spin detector, all elements may need to be fast. For instance an embodiment of the detector according to the present invention has the following specification (typical values are given in the following): wire bonds: about 6 GHz (flip-chip connections would be: about 10 GHz), feed throughs and cabling in the cryostate for low T measurements: about 5-6 GHz, signal and delay generators: about 10 GHz, detector (e.g., an oscilloscope): about 20 GHz, coplanar wave guides: about 40 GHz. The lowest frequency of the whole chain determines the performance of the system. At low temperatures this corresponds to about 5 GHz or a spin flip time of about 200 ps. At room temperature, this would correspond to about 10 GHz or a spin flip time of about 100 ps. Current microprocessors and integrated circuits already run at these speeds.

An ultra fast detector may need ultra fast contacts. For embodiment of the present invention related to the time-resolved measurement and device therefore, such an ultra fast contact—and moreover ultra fast chain of other elements or components needs to be present.

In another embodiment, one or more of such ultrafast contacts may be advantageous.

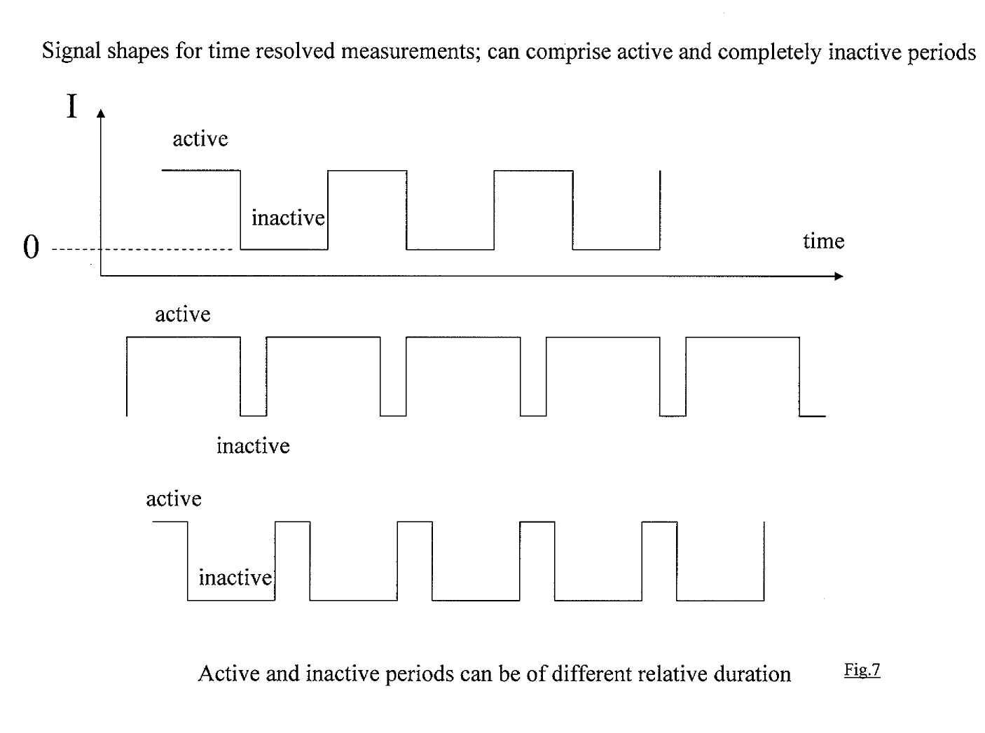

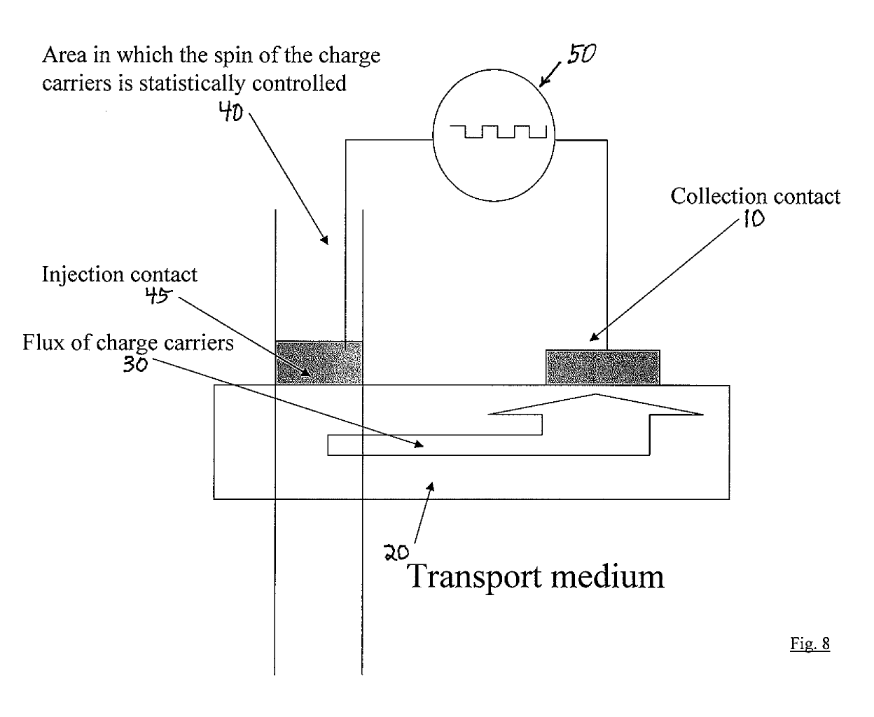

One of the elements in a chain of elements/components, making up a spin detector, is the injection means, which needs to be ultrafast for certain embodiments of the present invention related to the time-resolved measurement and device therefore. FIG. 7 shows some typical signals which may be used for the method and devices relating to the time resolved measurements. The active and inactive periods may have different lengths. One may be longer or shorter than the other. FIG. 8 shows how such a signal 50 may be applied to a device according to an embodiment of the present invention. Injection means include:
electrical injection using a fast contact, wherein the distance between an injection contact and a detection contact is smaller than spin flip length (the distance traveled in the spin flip time).
optical injection using fast circularly polarized optical beam.
any circuit that performs a fast calculation/manipulation that results in spin-polarized carriers.

In another embodiment, ultrafast injection contacts may also be advantageous.

A further object of certain embodiments of the present invention is a method for electrical spin detection using one or more ultrafast contacts. The description below is given for an exemplary embodiment comprising one ultrafast contact. It may also be used with two or more ultrafast contacts, where it can e.g. combine the improvements of the differential measurement method of certain embodiments of this invention with the benefits of the ultrafast measurements. The implementation of this kind of combination is straightforward to one of skill in the art and is therefore not detailed here.

The method for electrical spin detection using one or more ultrafast contacts comprises the following steps:
optionally prepare the medium 20 in an “empty” state or steady-state state, where empty means that the concentration of carriers of either type of spin is small compared to the amount of carriers that will be provided in the following step. In other words, even when all the carriers that remain at the end of this step would be collected by one of the contacts in the third step, then the corresponding current would be significantly smaller than the largest of the current resulting from the carriers injected in the second step
prepare/inject quickly
detect quickly [=within spin-relaxation time of the start of injection]
stop injecting

optionally the method may comprise emptying the transport medium 20 such that a new measurement can be performed, e.g., by performing one of the following:
by waiting several times the spin relaxation time (such that all carriers can be absorbed by the single contact, independent of their initial spin)
by having a second contact with opposite spin polarization that removes the type of spins that are not removed by the first contact. If this contact also has ultrafast connections and if its current is compared with that of the first contact, then this is an ultrafast differential method
by having a second contact that removes both types of spin. If this contact also has ultrafast connections and if its current is compared with that of the first contact, then this is an ultrafast differential method
letting the carriers recombine with carriers with an opposite charge (electrons with holes, or holes with electrons). These carriers with an opposite charge can e.g. be the result of doping, or of a contact that injects these carriers, or be generated at the same time as the original barriers when an ultrafast light beam is used to excite electron-hole pair.

Other embodiments and modifications than those described above are also included within the scope of the invention which is defined below in the claims.

1. A method for spin detection of charge carriers having a spin and forming a flux in a transport medium, comprising:
providing a flow of charge carriers from a starting point at a specific starting time to a first collection contact through the transport medium, wherein the first collection contact is in electrical contact with the transport medium and the charge carriers travel from the starting point to the first collection contact in a first travel time period,
measuring a first current of charge carriers during a measuring time period in the first collection contact, the first collection contact having a first spin selectivity, and
removing the charge carriers having a spin state for which the first collection contact is not selective,
wherein the sum of the measuring time period and the first travel time period is smaller than an average spin flip time of the charge carriers and wherein removing the charge carriers comprises providing a waiting time in which no flux is present in the transport medium, wherein the waiting time is higher than the average spin flip time.

2. The method of claim 1, further comprising deriving the spin state of a flux of charge carriers during the measuring time period.

3. The method of claim 1, further comprising determining a current integral over time of the current of charge carriers in the first collection contact over the measuring time period.

4. The method of claim 1, further comprising measuring a second current in a second collection contact in electrical contact with the transport medium, the second collection contact having a second spin selectivity different from the first spin selectivity, and wherein removing the charge carriers comprises the charge carriers traveling from the starting point to the second collection contact in a second travel time period.

5. The method of claim 4, further comprising comparing the measured first current and the measured second current.

6. The method of claim 5 wherein the measuring is started when the spin of the charge carriers is in a steady state.

7. The method of claim 5, further comprising:
determining a first current integral in time for the first current over a first time period,
determining a second current integral in time for the second current over a second time period, and
comparing the first current integral and the second current integral.

8. The method as in claim 7, wherein the first time period starts after the sum of the starting time and the first travel time and the second time period starts after the sum of the starting time and the second travel time.

9. The method of claim 7, wherein the first time period is smaller than the average spin flip time minus the first travel time and second time period is smaller than the average spin flip time minus the second travel time.

10. The method of claim 4, wherein the charge carriers have a spin diffusion length, and the first collection contact and the second collection contact has a distance between them that is smaller than the spin diffusion length.

11. The method of claim 1, wherein the transport medium comprises a semiconductor.
